(19) United States
(12) Patent Application Publication
(10) Pub. No.: US 2015/0184000 A1
(43) Pub. Date: Jul. 2, 2015

(54) HALOGEN DOPING SOURCE FOR DOPING OXIDE THIN FILM WlTH HALOGEN USING ATOMlC LAYER DEPOSITION, METHOD FOR MANUFACTURING THE HALOGEN DOPING SOURCE, METHOD FOR DOPING OXIDE THIN FILM WlTH HALOGEN USING ATOMIC LAYER DEPOSITlON, AND OXIDE THIN FILM DOPED WITH HALOGEN MANUFACTURED BY USING THE METHOD FOR DOPING OXIDE THIN FILM WITH HALOGEN

(71) Applicant: Industry-Academic Cooperation Foundation, Yonsei University, Seoul (KR)

(72) Inventors: HyungHo Park, Seoul (KR); YongJune Choi, Seoul (KR); KyungMun Kang, Seoul (KR)

(21) Appl. No.: 14/468,421

(22) Filed: Aug. 26, 2014

(30) Foreign Application Priority Data
Aug. 26, 2013 (KR) 10-2013-0100908

(51) Int. Cl. C09D 5/24; H01L 21/02; H01L 21/385

(52) U.S. Cl. CPC C09D 5/24; H01L 21/385; H01L 21/02565; H01L 21/0257; H01L 21/0262

(57) ABSTRACT

A halogen doping source for doping part of an oxide thin film with halogen by atomic layer deposition, a method of manufacturing the same halogen doping source, a method of doping part of an oxide thin film with the same halogen doping source by atomic layer deposition and a halogen-doped oxide thin film fabricated by the same doping method. The halogen doping source is a solution in which a hydrogen halide is diluted with water. The hydrogen halide diluted in 48 to 51% is prepared and subsequently added to deionized water, thereby forming a diluted solution. A substrate on which an oxide thin film is formed is loaded into an atomic layer deposition chamber. The diluted solution is sprayed into the chamber, whereby part of the oxide thin film is substituted with the halogen.

### CROSS REFERENCE TO RELATED APPLICATION

The present application claims priority from Korean Patent Application Number 10-2013-100908 filed on Aug. 26, 2013, the entire contents of which are incorporated herein for all purposes by this reference.

### BACKGROUND OF THE INVENTION

1. Field of the Invention

The present invention relates to a halogen doping source for doping part of an oxide thin film with halogen by atomic layer deposition and a method of manufacturing the same halogen doping source. The present invention also relates to a method of doping part of an oxide thin film with the same halogen doping source by atomic layer deposition and a halogen-doped oxide thin film fabricated by the same doping method.

2. Description of Related Art

A variety of methods is known to vary the electrical, optical and structural characteristics of a metal oxide by doping part of the metal oxide with a different element when depositing the metal oxide on a substrate. Doping the metal oxide with a halogen, i.e. substituting some of the oxygen atoms in the metal oxide with halogen atoms, is known to be extremely difficult due to the volatility of the halogen. Regardless of such difficulty, several technologies, such as spray pryolysis, chemical vapor deposition (CVD), sputtering, electron beam (E-beam) evaporation and pulsed laser deposition, are known to be used to substitute some of the oxygen atoms in the metal oxide with halogen atoms.

Among these technologies, CVD is a deposition method of directly depositing a gaseous metal oxide onto a substrate using a metal-organic precursor. CVD is advantageous in that operation conditions are clean and thin films having a uniform surface can be fabricated. In particular, as a case in which a metal oxide thin film is doped with a halogen using CVD, a method for improving the electrical characteristics of a zinc oxide (ZnO) thin film by doping the ZnO thin film with fluorine (F) was reported in the art.

However, the fabrication of a thin film by the above-mentioned method 400° C. or higher. Since operations at this high temperature disadvantageously change the characteristics of a compound, it is difficult to apply this method to high-precision fields, such as displays, or next-generation electronic devices to which flexible substrates are used.

In order to overcome the foregoing problems and fabricate simpler and higher-quality thin films, recently, atomic layer deposition (ALD) based on CVD is being actively studied as a new deposition method of metal oxide thin films. Since ALD forms a thin film by depositing atomic layers, thickness control is easy and step coverage is excellent. It is therefore advantageous in that a uniform thin film can be deposited on a variety of complicated substrates or structures. In addition, it is possible to deposit a thin film at a low temperature of 200° C. or less since its formation temperature is very low. Source materials used in ALD are identical to organic metal precursors used in CVD. At present, most organic metal precursors of, for example, metal and metal oxides, used for depositing ceramic thin films are commercially available. In practice, the organic metal precursors are often used in deposition processes for semiconductor devices and transparent electrode thin films. However, no source material for ALD or CVD has been yet developed from a non-metal material such as a halogen. For example, in order to use fluorine from among halogen elements in ALD, proposed was a method of depositing a metal fluoride, such as MgF₂ or CdF₂, using a fluorinated metal, such as TiF₄ or TaF₅, as a fluorine source material. However, when a metal fluoride thin film is fabricated by this method using TiF₄ or TaF₅, metal atoms such as Ti or Ta are concurrently deposited on the thin film, causing the problem of contamination caused by an undesirable heterogeneous element such as Ti or Ta. Therefore, no halogen such as F can be used as a doping source in the form of TiF₄ or TaF₅ when depositing a metal oxide by ALD.

The information disclosed in the Background of the Invention section is provided only for better understanding of the background of the invention and should not be taken as an acknowledgment or any form of suggestion that this information forms a prior art that would already be known to a person skilled in the art.

### BRIEF SUMMARY OF THE INVENTION

Various aspects of the present invention provide a halogen doping source that can be used when depositing an oxide thin film by atomic layer deposition (ALD).

Also provided is a method of doping part of an oxide thin film with a desired content of halogen using the halogen doping source by ALD.

Also provided are an oxide thin film, part of which is doped with a desired content of halogen by ALD, and a substrate on which the oxide thin film is formed. The oxide thin film is not contaminated by an undesirable heterogeneous element, the amount by which the oxide thin film is doped can be quantitatively controlled, and the oxide thin film can be doped with the halogen with high accuracy.

Also provided are a method capable of easily controlling the surface shape of an oxide thin film by controlling the preferred orientation of the oxide thin film through easy adjustment of the doping ratio of the halogen, an oxide thin film, the surface shape of which is controlled by the same method, and a substrate on which the oxide thin film is formed.

In an aspect of the present invention, provided is a halogen doping source for doping at least part of an oxide thin film by atomic layer deposition. The halogen doping source includes a solution in which a hydrogen halide is diluted with water.

The hydrogen halide may include at least one selected from the group consisting of hydrogen fluoride, hydrogen chloride, hydrogen bromide and hydrogen iodide.

In this case, the solution may be a diluted solution having a composition that includes at least 5 ml deionized water per 1 ml hydrogen fluoride.

In another aspect of the present invention, provided is a method of manufacturing a halogen doping source for doping an oxide thin film by atomic layer deposition. The method includes the following steps of: preparing a hydrogen halide or a water-diluted hydrogen halide; and forming a diluted solution by adding the hydrogen halide or the water-diluted hydrogen halide to deionized water.

The hydrogen halide may be at least one selected from the group consisting of hydrogen fluoride, hydrogen chloride, hydrogen bromide and hydrogen iodide.

In this case, the solution may be a diluted solution having a composition that includes at least 5 ml deionized water per 1 ml hydrogen fluoride.

In a further aspect of the present invention, provided is a method of doping part of an oxide thin film with a halogen by atomic layer deposition using an atomic layer deposition apparatus which includes a chamber into which a substrate is to be loaded and a plurality of source canisters each containing a thin film forming source. The method includes: a first step of loading a substrate on which a metal oxide thin film is to be formed into the chamber; a second step of forming a diluted solution by adding a hydrogen halide or a water-diluted hydrogen halide into deionized water; a third step of containing the diluted solution and a metal source material of the metal oxide thin film to be formed in the source canisters; a fourth step of spraying the metal source material of the metal oxide thin film into the chamber; and a fifth step of spraying the diluted solution into the chamber.

The fourth step and the fifth step may be repeated in a plurality of times.

In another aspect of the present invention, provided is a method of doping part of an oxide thin film with a halogen by atomic layer deposition using an atomic layer deposition apparatus which includes a chamber into which a substrate is to be loaded and a plurality of source canisters each containing a thin film forming source. The method includes: a first step of loading a substrate on which a metal oxide thin film is to be formed into the chamber; a second step of forming a diluted solution by adding a hydrogen halide or a water-diluted hydrogen halide into deionized water; a third step of containing the diluted solution, a metal source material of the metal oxide thin film to be formed and water in the source canisters; a fourth step of spraying the metal source material of the metal oxide thin film into the chamber; and a fifth step of spraying the diluted solution or the water into the chamber.

The fourth step and the fifth step may be repeated in a plurality of times.

In this case, the fifth step may regularly repeat spraying the diluted solution into the chamber and spraying the water into the chamber according to a predetermined ratio.

The method may further include the step of removing residue from the chamber after the fourth step.

The method may further include the step of removing residue from the chamber after the fifth step.

The doping amount of the halogen may be controlled according to the concentration of the diluted solution.

The doping amount of the halogen may be controlled according to the ratio between the number of times for spraying the diluted solution into the chamber and the number of times for spraying the water into the chamber at the fifth step.

The hydrogen halide may be at least one selected from the group consisting of hydrogen fluoride, hydrogen chloride, hydrogen bromide and hydrogen iodide.

In this case, the diluted solution may have a composition that includes at least 5 ml deionized water per 1 ml hydrogen fluoride.

In a further aspect of the present invention, provided is an oxide thin film fabricated by the method of doping part of an oxide thin film with a halogen by atomic layer deposition.

As set forth above, the use of the halogen doping source according to an embodiment of the present invention makes it possible to form a metal oxide thin film doped with a halogen by quantitatively doping the halogen into the oxide thin film by ALD.

In addition, when an oxide thin film is doped with a halogen by ALD using the halogen doping source according to an embodiment of the present invention, it is possible to produce an oxide thin film which is not contaminated by an undesirable heterogeneous element, the doping ratio of which can be quantitatively controlled, and which can be doped with the halogen with high accuracy, as well as a substrate on which the oxide thin film is formed.

Furthermore, it is possible to produce an oxide thin film, the surface shape of which can be controlled by controlling the preferred orientation of the oxide thin film through quantitative adjustment of the doping ratio of a halogen, and a substrate on which the oxide thin film is formed.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a view schematically illustrating a method of manufacturing a doping source for doping an oxide thin film with F according to an exemplary embodiment of the present invention;

FIG. 2 illustrates FE-SEM pictures of ZnO thin films that were doped with F using a F doping source produced by diluting HF with water according to an exemplary embodiment of the present invention;

FIG. 3 is a view illustrating the relationship between the source spray ratio and the doping amount of F in F-doped ZnO thin films according to an exemplary embodiment of the present invention;

FIG. 4 illustrates FE-SEM pictures of ZnO thin films that were doped with Cl using a Cl doping source produced by diluting HCl with water according to an exemplary embodiment of the present invention;

FIG. 5 is a view illustrating the result of EDX quantitative analysis on ZnO thin films that were doped with F using a F doping source manufactured according to an exemplary embodiment of the present invention; and

FIG. 6 is a view illustrating the result of PES analysis on a ZnO thin film doped with Cl using a Cl doping source manufactured according to an exemplary embodiment of the present invention.

### DETAILED DESCRIPTION OF THE INVENTION

Reference will be now made in detail to a halogen doping source for doping part of an oxide thin film with halogen by ALD, a method of manufacturing the same halogen doping source, a method of doping part of an oxide thin film with the same halogen doping source by ALD, and a halogen-doped oxide thin film fabricated by the same doping method according to an exemplary embodiment of the present invention.

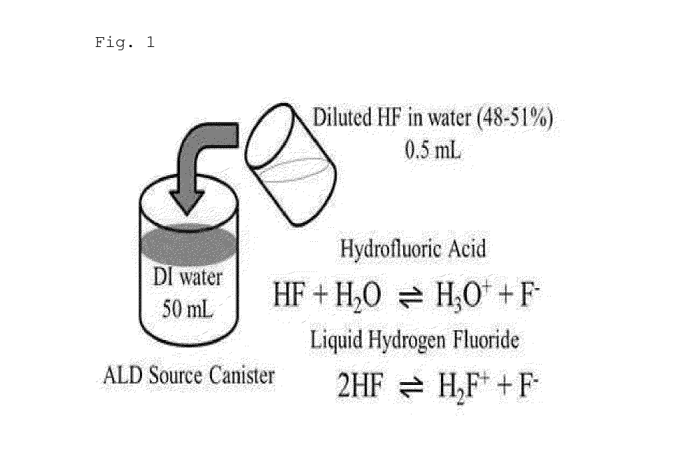

FIG. 1 is a view schematically illustrating a method of manufacturing a doping source for doping an oxide thin film with fluorine (F) according to an exemplary embodiment of the present invention. As illustrated in FIG. 1, a halogen doping source, more particularly, a F doping source for doping F, according to an exemplary embodiment of the present invention is prepared by diluting hydrogen fluoride (HF) with water to a concentration ranging from 48 to 51% and providing a diluted mixture solution in which 50 ml deionized (DI) water is mixed per 0.5 ml HF.

Although FIG. 1 illustrates the F doping source using HF as a base, a variety of other halogen doping sources can be produced by diluting a variety of other hydrogen halides, such as hydrogen chloride (HCl), hydrogen bromide (HBr) or hydrogen iodide (HI), with water according to the type of halogen to be added. For example, according to an exemplary embodiment of the present invention, a diluted mixture solution was prepared by mixing 50 ml deionized water per 0.5 ml HCl diluted to a concentration ranging from 33 to 40%, and part of an oxide thin film was doped with F using the diluted mixture solution.

According to this embodiment, an atomic layer deposition apparatus was used in order to perform atomic layer deposition. More specifically, the atomic layer deposition apparatus used in this embodiment includes a chamber into which a substrate is to be loaded and a plurality of source canisters which contain thin film-forming sources. It is preferable that the plurality of source canisters includes at least a first source canister which contains a metal source for forming a metal oxide thin film, a second source canister which contains water, and a third source canister which contains a diluted solution in which a hydrogen halide is diluted with water.

Alternatively, a modified embodiment of the atomic layer deposition apparatus may include only the first source canister which contains a metal source for forming a metal oxide thin film and the third source canister which contains a diluted solution in which a hydrogen halide is diluted with water without the second source canister which contains water.

In addition, the atomic layer deposition apparatus according to an exemplary embodiment of the present invention includes, but not limited to, a spray unit which sprays the sources contained in the source canisters into the chamber, a discharge unit which discharges the metal source from the chamber, and a control unit which controls the operation of the deposition apparatus. Although detailed descriptions of these parts are omitted since they are well known to a person skilled in the art, they will be incorporated herein.

A description will be given below of a method of forming an oxide thin film that is doped with a halogen using the atomic layer deposition apparatus and the halogen doping source as described above.

At a first step, a substrate on which a metal oxide thin film is to be formed is loaded into the chamber of the atomic layer deposition apparatus. The substrate is typically implemented as a silicon (Si) substrate, but any types of substrates on which a metal oxide can be formed can be used.

Afterwards, at a second step, a diluted solution is formed by adding a hydrogen halide or a water-diluted hydrogen halide into deionized water. That is, the diluted solution can be the solution that was described in the former embodiment.

In addition, the metal oxide may not be doped with a desirable amount of the halogen if the diluted solution is too thin and corrosion may occur if the diluted solution is too thick. Therefore, in consideration of these characteristics, the concentration of the diluted solution is preferably maintained in the range that is equal to or greater than the concentration where the metal oxide can be doped with a desirable amount of the halogen and is equal to or smaller than the concentration where corrosion occurs. When there is a concern about corrosion due to the high concentration of the halogen, those parts which contact the halogen, such as the source canisters and ducts, can be made of a material coated with, for example, Teflon, in order to prevent corrosion. It is then possible to increase the concentration of the diluted solution. In this fashion, the concentration of the halogen can be set to a variety of values.

Subsequently, at a third step, the diluted solution, a metal source material of the metal oxide thin film to be formed and water are contained in the source canisters, respectively. Water may not be contained in the source canister.

Afterwards, at a fourth step, the metal source of the metal oxide thin film is sprayed into the chamber. According to an exemplary embodiment of the present invention, it is possible to use diethylzinc (DEZ) as the metal source in order to form, for example, a ZnO thin film. A variety of metal sources can be used according to the types of metal oxide thin films to be formed.

When the metal source is sprayed into the chamber, the metal is deposited on the substrate. In addition, residue, such as a material separated from the substrate and materials supplied from the source canisters, may reside inside the chamber after the spraying process. It is preferable that this residue be removed from the chamber.

Subsequently, at a fifth step, the diluted solution or water in the source canister is sprayed into the chamber. Consequently, oxygen of H₂O and the halogen (F, Cl, Br or I) of the hydrogen halide in the diluted solution can be bonded with the metal, thereby forming the metal oxide doped with the halogen. Since the level at which the metal oxide thin film is doped is in principle proportional to the concentration of the diluted solution, it is possible to easily control the amount by which the metal oxide thin film is doped by adjusting the concentration of the diluted solution. According to the present invention, the amount by which the metal oxide thin film is doped is saturated at a preset level even if the concentration of the diluted solution is further increased, and corrosion may occur if the concentration of the diluted solution is excessively increased. It is therefore preferable that the concentration of the diluted solution be properly limited. When there is a concern about corrosion due to the high concentration of the halogen, those parts, such as the source canisters and ducts, which contact the halogen can be made of a material coated with, for example, Teflon, in order to prevent corrosion. It is then possible to increase the concentration of the diluted solution. In this fashion, the concentration of the halogen can be set to a variety of values. It should be understood, however, that residue may remain inside the chamber after the spraying process of the fifth step. It is preferable that this residue be removed from the chamber.

According to this method, it is possible to a desirable thickness of the metal oxide thin film doped with a desirable amount of halogen by sequentially repeating the fourth and fifth steps as many cycles as desired.

Alternatively, according to another embodiment of the present invention, it is possible to substitute the above-mentioned method of manufacturing a doped metal oxide thin film by alternately spraying the metal source and the diluted solution with a method of manufacturing an oxide thin film doped with a halogen by selectively spraying the diluted solution and water at the step of spraying the diluted solution and repeating the above-mentioned cycles.

According to this embodiment, when performing the fourth step and then the fifth step once is defined as one cycle, after the metal source is sprayed at the fourth step, the diluted solution and water at the fifth step can be selectively sprayed according to the cycle. For example, when intended to spray water and the diluted solution at a ratio of 4:1, the process of spraying water at the fifth step after spraying the metal source is performed for 4 cycles, and subsequently the metal source and the diluted solution are sprayed once. According to this embodiment, it is possible to control the amount by which the metal oxide thin film is doped by spraying water and the diluted solution at a preset ratio as described above.

The former embodiment is to control the amount by which the metal oxide thin film is doped according to the concentration of the diluted solution, whereas the latter embodiment is to control the amount by which the metal oxide thin film is doped according to the amounts by which the diluted solution and water are sprayed. In the latter embodiment, the doping amount is saturated at a preset level even if the concentration of the diluted solution is further increased, and corrosion may occur if the concentration of the diluted solution is excessively increased. It is therefore preferable that the concentration of the diluted solution be properly limited.

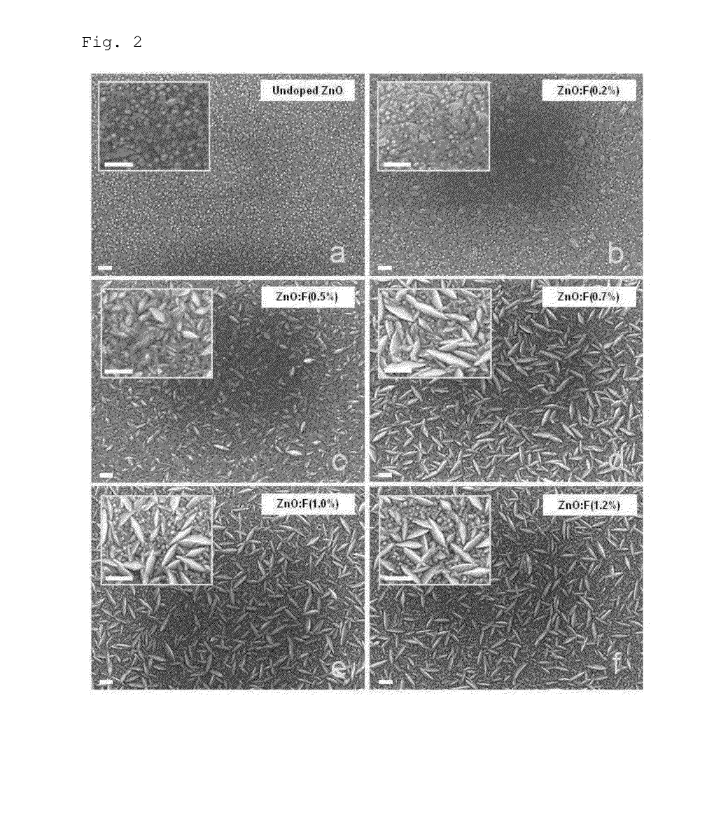

FIG. 2 illustrates field emission scanning microscopy (FE-SEM) pictures of zinc oxide (ZnO) thin films that were doped with fluorine (F) using a F doping source produced by diluting hydrogen fluoride (HF) with water according to an exemplary embodiment of the present invention.

FIG. 2 illustrates the amounts by which the ZnO thin films were doped and the states of the doped structures. Here, the ZnO thin films doped with F were formed using diethylzinc (DEZ), a diluted solution where HF was diluted using 100 ml water per 0.5 ml HF and water, which were contained in the source canisters of the atomic layer deposition apparatus, respectively, and by sequentially spraying the diluted solution and water in a variety of preset sequences in the following method. Specifically, part “a” of FIG. 2 illustrates the state of the oxide thin film which is not doped with F, manufactured by spraying only DEZ and water without spraying the diluted solution. Part “b” of FIG. 2 illustrates the state of the doped ZnO thin film when DEZ/water and DEZ/diluted solution were sprayed at a 4:1 ratio. Part “c” of FIG. 2 illustrates the state of the doped ZnO thin film when DEZ/water and DEZ/diluted solution were sprayed at a 2:1 ratio. Part “d” of FIG. 2 illustrates the state of the doped ZnO thin film when DEZ/water and DEZ/diluted solution were sprayed at a 1:1 ratio. Part “e” of FIG. 2 illustrates the state of the doped ZnO thin film when DEZ/water and DEZ/diluted solution were sprayed at a 2:1 ratio. Part “f” of FIG. 2 illustrates the state of the doped ZnO thin film when DEZ/water was not sprayed and only DEZ/diluted solution was sprayed.

As illustrated in FIG. 2, it is appreciated that the F contents (doping ratio) within the ZnO thin film were 0.2%, 0.5%, 0.7% and 1.0% when the spraying ratios of water and the diluted solution, which were sprayed after DEZ, was 4:1, 2:1, 1:1 and 1:4. In addition, when only the diluted solution was sprayed without water, 1.2% of the ZnO thin film was doped.

In addition, as illustrated in part “a” of FIG. 2, the columnar shape of undoped ZnO indicates crystal grains grown in the (002) direction, and the wedge-like shape of undoped ZnO indicates crystal grains grown in the (100) direction. As illustrated in part “b” to “f” of FIG. 2, it is appreciated that the preferred orientation of ZnO crystals gradually changed from the (002) direction to the (100) direction with the doping ratio of F increasing.

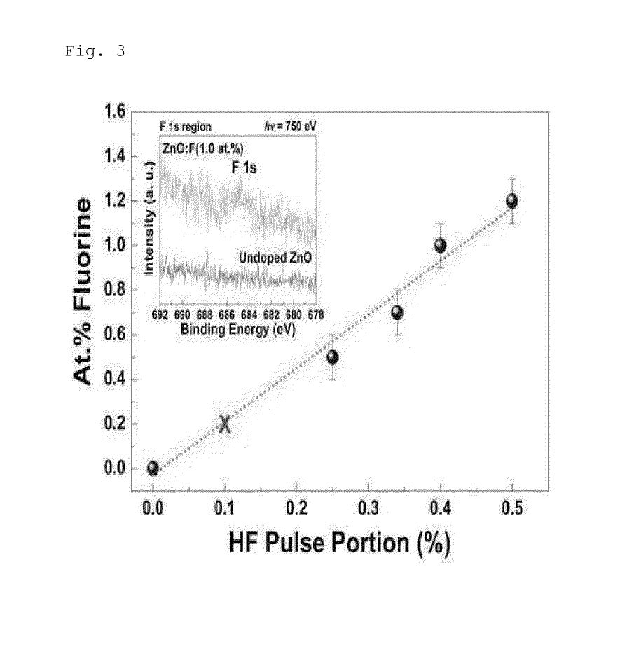

FIG. 3 is a view illustrating changes in the doping ratio when the spraying ratio of water and the diluted solution shown in FIG. 2 was adjusted, i.e. the relationship between the content of HF and the doping ratio (the F content within the ZnO thin film) when water and the diluted solution were sprayed at a variety of ratios. As illustrated in FIG. 3, it is appreciated that the content of HF and the doping ratio linearly increase. This indicates that the doping ratio of the metal oxide thin film can be controlled by adjusting the amount of hydrogen halide sprayed, for example, by adjusting the concentration of the diluted solution or the spraying ratio of the diluted solution and water.

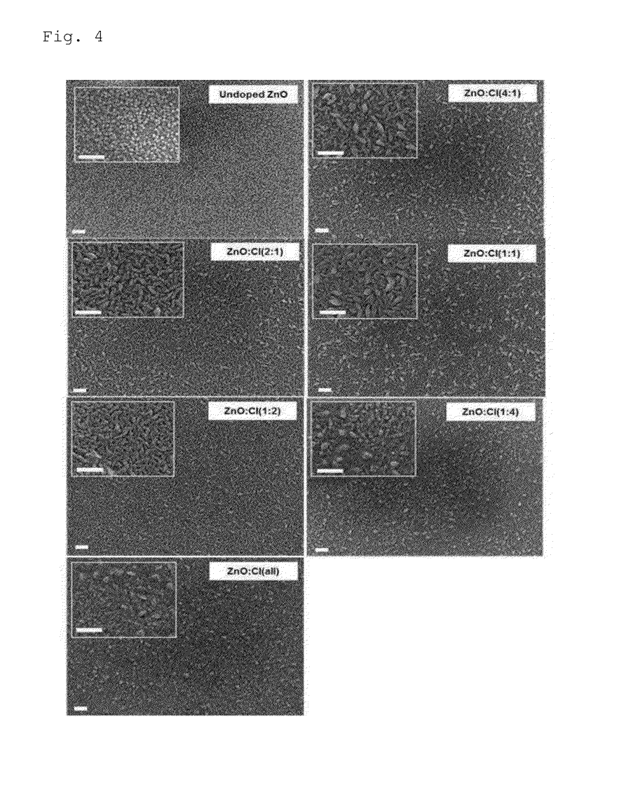

FIG. 4 illustrates field emission scanning microscopy (FE-SEM) pictures of ZnO thin films that were doped with chlorine (Cl) using a Cl doping source produced by diluting hydrogen chloride (HCl) with water in a method similar to that of FIG. 2.

Specifically, the pictures illustrate the states of Cl-doped ZnO thin films sequentially from the left top when only DEZ and water were sprayed without the diluted solution being sprayed, when DEZ/water and DEZ/diluted solution were sprayed at ratios of 4:1, 2:1, 1:1, 1:2 and 1:4, and when only DEZ and the diluted solution were sprayed.

As illustrated in FIG. 4, the columnar shape of undoped ZnO indicates crystal grains grown in the (002) direction, and the wedge-like shape of undoped ZnO indicates crystal grains grown in the (100) direction. It is appreciated that the preferred orientation of ZnO crystals gradually changed from the (002) direction to the (100) direction with the doping ratio of Cl increasing.

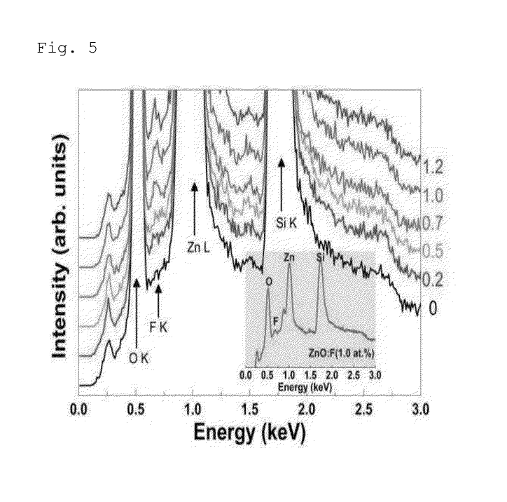

FIG. 5 is a view illustrating the result of energy-dispersive X-ray spectroscopy (EDX) analysis on a ZnO thin film doped with F using a F doping source diluted with water. As illustrated in FIG. 5, the ZnO thin film was finely doped with F, and the doping ratio was accurately controlled through the cycle adjustment of the doping source.

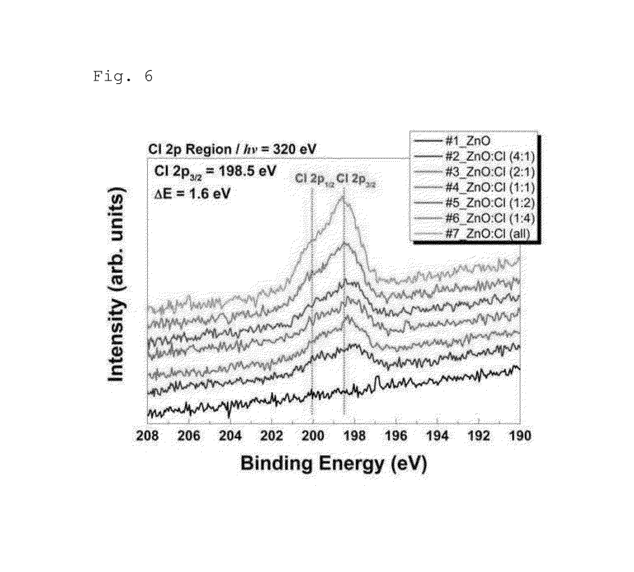

FIG. 6 is a view illustrating the result of photoemission spectroscopy (PES) analysis on a ZnO thin film doped with Cl using a Cl doping source manufactured according to an exemplary embodiment of the present invention. As illustrated in FIG. 6, the amount by which the ZnO thin film was doped shows a linear increase with the doping ratio of HCl increasing.

Although the halogen doping source for doping part of an oxide thin film with halogen by ALD, the method of manufacturing the same halogen doping source, the method of doping part of an oxide thin film with the same halogen doping source by ALD, and the halogen-doped oxide thin film fabricated by the same doping method according to an exemplary embodiment of the present invention have been described in detail hereinbefore, a person skilled in the art can make a variety of modifications and alterations. It is intended, therefore, that the scope of the invention be defined by the Claims appended hereto and their equivalents.

What is claimed is:

1. A halogen doping source for doping at least part of an oxide thin film by atomic layer deposition, the halogen doping source comprising a solution in which a hydrogen halide is diluted with water.

2. The halogen doping source according to claim 1, wherein the hydrogen halide comprises at least one selected from the group consisting of hydrogen fluoride, hydrogen chloride, hydrogen bromide and hydrogen iodide.

3. The halogen doping source according to claim 1, wherein the solution is a diluted solution having a composition that includes at least 5 ml deionized water per 1 ml hydrogen fluoride.

4. A method of manufacturing a halogen doping source for doping an oxide thin film by atomic layer deposition, the method comprising:
preparing a hydrogen halide or a water-diluted hydrogen halide; and
forming a diluted solution by adding the hydrogen halide or the water-diluted hydrogen halide to deionized water.

5. The method according to claim 4, wherein the hydrogen halide comprises at least one selected from the group consisting of hydrogen fluoride, hydrogen chloride, hydrogen bromide and hydrogen iodide.

6. The method according to claim 4, wherein the solution comprises a diluted solution having a composition that includes at least 5 ml deionized water per 1 ml hydrogen fluoride.

7. A method of doping part of an oxide thin film with a halogen by atomic layer deposition using an atomic layer deposition apparatus which includes a chamber into which a substrate is to be loaded and a plurality of source canisters each containing a thin film forming source, the method comprising:
a first step of loading a substrate on which a metal oxide thin film is to be formed into the chamber;
a second step of forming a diluted solution by adding a hydrogen halide or a water-diluted hydrogen halide into deionized water;
a third step of containing the diluted solution and a metal source material of the metal oxide thin film to be formed in the source canisters;
a fourth step of spraying the metal source material of the metal oxide thin film into the chamber; and
a fifth step of spraying the diluted solution into the chamber.

8. The method according to claim 7, comprising repeating the fourth step and the fifth step in a plurality of times.

9. A method of doping part of an oxide thin film with a halogen by atomic layer deposition using an atomic layer deposition apparatus which includes a chamber into which a substrate is to be loaded and a plurality of source canisters each containing a thin film forming source, the method comprising:
a first step of loading a substrate on which a metal oxide thin film is to be formed into the chamber;
a second step of forming a diluted solution by adding a hydrogen halide or a water-diluted hydrogen halide into deionized water;
a third step of containing the diluted solution, a metal source material of the metal oxide thin film to be formed and water in the source canisters;
a fourth step of spraying the metal source material of the metal oxide thin film into the chamber; and
a fifth step of spraying the diluted solution or the water into the chamber.

10. The method according to claim 9, comprising repeating the fourth step and the fifth step in a plurality of times.

11. The method according to claim 10, wherein the fifth step comprises regularly repeating spraying the diluted solution into the chamber and spraying the water into the chamber according to a predetermined ratio.

12. The method according to claim 7, further comprising a step of removing residue from the chamber after the fourth step or the fifth step.

13. The method according to claim 9, further comprising a step of removing residue from the chamber after the fourth step or the fifth step.

14. The method according to claim 7, comprising controlling a doping amount of the halogen according to a concentration of the diluted solution.

15. The method according to claim 9, comprising controlling a doping amount of the halogen according to a concentration of the diluted solution.

16. The method according to claim 9, comprising controlling a doping amount of the halogen according to a ratio between a number of times for spraying the diluted solution into the chamber and a number of times for spraying the water into the chamber at the fifth step.

17. The method according to claim 7, wherein the hydrogen halide comprises at least one selected from the group consisting of hydrogen fluoride, hydrogen chloride, hydrogen bromide and hydrogen iodide.

18. The method according to claim 9, wherein the hydrogen halide comprises at least one selected from the group consisting of hydrogen fluoride, hydrogen chloride, hydrogen bromide and hydrogen iodide.

19. The method according to claim 18, wherein the diluted solution has a composition that includes at least 5 ml deionized water per 1 ml hydrogen fluoride.
